(19) United States
(12) Patent Application Publication
(10) Pub. No.: US 2023/0187429 A1
(43) Pub. Date: Jun. 15, 2023

(54) LED DISPLAY

(71) Applicant: TOYODA GOSEI CO., LTD., Kiyosu-shi (JP)

(72) Inventor: Koichi GOSHONOO, Kiyosu-shi (JP)

(21) Appl. No.: 18/077,574

(22) Filed: Dec. 8, 2022

(30) Foreign Application Priority Data
Dec. 15, 2021 (JP) 2021-203768

(51) Int. Cl. H01L 25/16; H01L 33/20; H01L 33/38; H01L 23/00

(52) U.S. Cl. CPC H01L 25/167; H01L 24/13; H01L 24/29; H01L 33/20; H01L 33/382; H01L 24/32; H01L 2224/13021; H01L 2224/29111; H01L 2224/29144; H01L 2224/32145; H01L 2924/0132; H01L 2924/12041

(57) ABSTRACT

The present invention provides a LED display miniaturized while suppressing bonding failure of electrode. A micro-LED element includes a substrate, a semiconductor layer, a p-electrode, and an n-electrode. The semiconductor layer has a plurality of light-emitting parts arranged in a matrix and having a light-emitting layer. The p-electrodes are arranged in a matrix corresponding to the positions of the light-emitting parts. The n-electrode is disposed annularly surrounding the light-emitting parts and the p-electrodes. The semiconductor layer has a central part and an outer peripheral part. The outer peripheral part has a p-type semiconductor layer.

### BACKGROUND OF THE INVENTION

### Field of the Invention

The present invention relates to a LED display.

### Background Art

A display device has been used in a variety of fields such as television, desktop computer, notebook computer, and smartphone. A micro-LED display has been researched and developed for image display. A micro-LED display has micro light-emitting elements of approximately 1 µm to 100 µm arranged in a matrix.

As a LED element, for example, a light-emitting device having gallium nitride-based semiconductor has been developed. Japanese Patent Application Laid-Open (kokai) No. H08-032116 discloses a gallium nitride compound light-emitting semiconductor device provided with a groove 9.

The micro-LED display has a monolithic structure in which a micro-LED element is integrally formed with a substrate. This monolithic display requires a driving circuit for emitting a light in the units of micro-LED element. The monolithic display is mounted face down on a substrate mounted with a driving circuit so that electrodes of each micro-LED element are bonded to pad electrodes of the mounting substrate. The LED element is preferably miniaturized. In a Group III nitride semiconductor light-emitting device, an n-type semiconductor layer, a light-emitting layer, and a p-type semiconductor layer are formed on a substrate. An n-electrode is formed on the n-type semiconductor layer. A p-electrode is formed on the p-type semiconductor layer through a transparent electrode.

In the miniaturized LED element, an n-electrode is bonded to the surface of the n-type semiconductor layer formed by etching until the n-type semiconductor layer is exposed from the p-type semiconductor layer. A surface to which the n-electrode is bonded is different in height from a surface to which the p-electrode is bonded. Therefore, when the n-electrode and the p-electrode are formed in the same process, the n-electrode and the p-electrode are different in lengths, i.e., heights, from the surface of the p-type semiconductor layer. As a result of this, when the LED element is mounted on the driving circuit substrate, a bonding failure occurs between the LED element and the driving circuit substrate.

### SUMMARY OF THE INVENTION

An object of the present invention is to prevent bonding failure when a micro-LED display is bonded to a circuit substrate.

In a first aspect of the present invention, there is a provided a LED display including a monolithic light-emitting element having a plurality of light-emitting parts formed on a substrate, and a driving circuit substrate having a driving circuit for emitting a light from the light-emitting element formed thereon. In the LED display, the light-emitting element includes the substrate, an n-type semiconductor layer, a light-emitting layer, a p-type semiconductor layer, a p-electrode, and an n-electrode. The light-emitting parts are arranged in a matrix. The p-electrodes are arranged in a matrix corresponding to the positions of the light-emitting parts. The light-emitting element has a groove surrounding a central part having the light-emitting parts formed therein, and dividing a part outside the central part as an outer peripheral part. The n-electrode is formed annularly along the groove, being in contact with the n-type semiconductor layer exposed on a bottom surface of the groove and surrounding the central part from a top surface of the outer peripheral part, the n-electrode being not contact with an inner wall surface on the central part side of the groove.

In the aspect of the above-mentioned invention, an electrode pad for bonding the p-electrode and the n-electrode is formed on a top surface of the driving circuit substrate, and the surfaces facing the electrode pads of the n-electrode and the p-electrode are preferably positioned on a level surface. This ensures bonding between the light-emitting element and the driving circuit substrate.

The n-electrode is preferably in contact with an outer wall surface facing the inner wall surface of the groove. Thereby, the outer peripheral part outside the groove can be made a non-light emitting region. The n-electrode is preferably formed on the p-type semiconductor layer as the top layer of the outer peripheral part. The height of the n-electrode can be made equal to the height of the p-electrode by forming the n-electrode on the top layer. A transparent electrode is preferably formed on the p-type semiconductor layer of the outer peripheral part. The n-electrode is preferably formed on the transparent electrode of the outer peripheral part. The height of the p-electrode can be equal to the height of the n-electrode by forming the transparent electrode as a top layer of both the central part and the outer peripheral part. The n-electrode has an outside surface facing the outside of the light-emitting element and an inside surface facing the inside of the light-emitting element. The inside surface of the n-electrode is preferably disposed between the inner wall surface and the outer wall surface of the groove. Moreover, the common n-electrode is preferably formed for a plurality of the light-emitting parts. Thus, electrons are uniformly supplied to the light-emitting parts of the central part from the surroundings, thereby achieving uniform light emission.

The semiconductor layer of the LED display has a central part surrounded by the n-electrode, and an outer peripheral part outside the central part. The n-electrode is formed on the outer peripheral part. The height of the n-electrode from the substrate is almost equal to the height of the p-electrode from the substrate. Thereby, bonding failure hardly occurs when the light-emitting element is mounted on the driving circuit substrate.

According to the present invention, bonding failure can be suppressed between the electrode of the monolithic light-emitting element and the electrode pad on the driving circuit substrate.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a schematic view of the structure of a LED display D1 according to a first embodiment;

FIG. 2 is a view showing the arrangement of electrodes in a micro-LED element 100 of the LED display D1 according to the first embodiment;

FIG. 3 shows the positional relationship between electrodes and groove U1 in the micro-LED element 100 of the LED display D1 according to the first embodiment, and is a figure viewing from the arrow direction of the III-III line of FIG. 1; and

FIG. 4 shows the structure of a LED display D2 having no outer peripheral part.

### DETAILED DESCRIPTION OF PREFERRED EMBODIMENTS

A specific embodiment of the LED display will next be described with reference to the drawings. However, the present invention is not limited to the embodiment. The deposition structure of the layers and the electrode structure of the below-described element are given only for the illustration purpose, and other disposition structures differing therefrom may also be employed. The thickness ratio and aspect ratio of the layers shown in the drawings are not an actual value, but a conceptual value.

### First Embodiment

### 1. LED Display

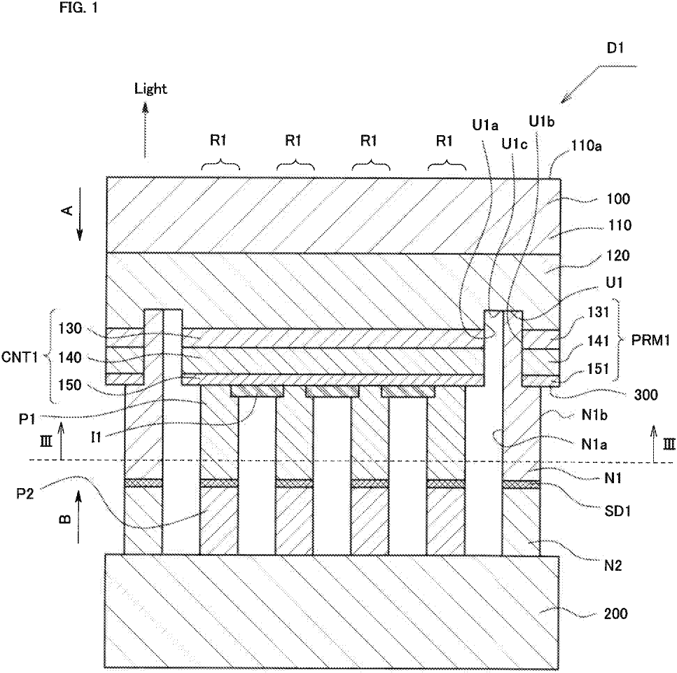

FIG. 1 is a schematic view of the structure of a LED display D1 according to a first embodiment. The LED display D1 includes a micro-LED element 100, and a driving circuit substrate 200. The micro-LED element 100 is mounted on the driving circuit substrate 200. As shown in FIG. 1, the micro-LED element 100 is a monolithic semiconductor light-emitting element. Light is output upward from a main surface 110a of the substrate 110 in FIG. 1.

The micro-LED element 100 includes a substrate 110, an n-type semiconductor layer 120, a light-emitting layer 130, a p-type semiconductor layer 140, a transparent electrode 150, an insulating layer I1, a p-electrode P1, and an n-electrode N1. Hereinafter, the direction shown by arrow A is upward direction for the LED element from the substrate 110 to the p-electrode and the n-electrode. The semiconductor layers, electrodes, and others are sequentially formed on the substrate 110.

The substrate 110 is a transparent substrate made of, for example, sapphire, GaN, or SiC. The n-type semiconductor layer 120, the light-emitting layer 130, and the p-type semiconductor layer 140 are a Group III nitride semiconductor layer. The transparent electrode 150 is made of transparent conductive oxide such as ITO and IZO. The insulating layer T1 is an insulating layer made of, for example, SiO₂ and others. The insulating layer I1 divides the light-emitting layer 130 into a plurality of light-emitting parts as described later.

The p-electrode P1 is formed on the transparent electrode 150. The p-electrode P1 is electrically connected to the p-type semiconductor layer 140 through the transparent electrode 150.

The n-electrode N1 is formed on the n-type semiconductor layer 120, and electrically connected to the n-type semiconductor layer 120. The n-electrode N1 is in contact with a non-light emitting part 131, a p-type semiconductor layer 141, and a transparent electrode 151 as described below, in addition to the n-type semiconductor layer 120.

For the driving circuit substrate 200, the direction shown by arrow B is upward direction in FIG. 1. A p-electrode pad P2, an n-electrode pad N2, and a driving circuit (not illustrated) are formed on the driving circuit substrate 200. The p-electrode P1 of the micro-LED element 100 is electrically connected to the p-electrode pad P2 of the driving circuit substrate 200 through a bonding layer SD1. The n-electrode N1 of the micro-LED element 100 is electrically connected to the n-electrode pad N2 of the driving circuit substrate 200 through the bonding layer SD1. The bonding layer SD1 is a metal or alloy bonding material. The bonding layer SD1 is, for example, Au-Sn-based solder. The driving circuit controls electrical conduction in the units of the micro-LED element.

As shown in FIG. 1, the semiconductor layer of the micro-LED element 100 has a plurality of light-emitting parts R1. The light-emitting parts R1 are arranged in a matrix. The light-emitting part R1 has the n-type semiconductor layer 120, the light-emitting layer 130, and the p-type semiconductor layer 140.

### 2. Central Part and Outer Peripheral Part

As shown in FIG. 1, a groove U1 for exposing the n-type semiconductor layer 120 is formed to form the n-electrode N1 on the n-type semiconductor layer 120. The semiconductor layer has a central part CNT1 and an outer peripheral part PRM1. The central part CNT1 and the outer peripheral part PRM1 are divided by the groove U1.

The central part CNT1 has the n-type semiconductor layer 120, the light-emitting layer 130, and the p-type semiconductor layer 140. The transparent electrode 150 is formed on the p-type semiconductor layer 140. The n-type semiconductor layer 120 is electrically connected to the n-electrode N1. The p-type semiconductor layer 140 is electrically connected to the p-electrode P1. The light-emitting layer 130 is disposed between the n-type semiconductor layer 120 and the p-type semiconductor layer 140. Therefore, when voltage is applied between the n-electrode N1 and the p-electrode P1, the light-emitting layer 130 emits light. Actually, a plurality of light-emitting parts R1 of the light-emitting layer 130 emit light.

The outer peripheral part PRM1 has the n-type semiconductor layer 120, the non-light emitting part 131, and the p-type semiconductor layer 141. The transparent electrode 151 is formed on the p-type semiconductor layer 141. The outer peripheral part PRM1 is not surrounded by the frame-shaped n-electrode N1. The n-electrode N1 is formed from a bottom surface U1c of the groove U1 over an outer wall surface U1b of the groove U1 of the outer peripheral part PRM1 and a part of a top surface of the transparent electrode 151. The side surfaces of the non-light emitting part 131 and the p-type semiconductor layer 141, and the top surface of the transparent electrode 151 of the outer peripheral part PRM1- are in contact with the n-electrode N1. However, the n-electrode N1 is not in contact with an inner wall surface U1a of the groove U1 of the outer peripheral part PRM1.

The n-type semiconductor layer 120, the non-light emitting part 131, and the p-type semiconductor layer 141 as a semiconductor layer of the outer peripheral part PRM1, are electrically connected to the n-electrode N1. Therefore, a potential difference is not generated between the n-type semiconductor layer 120 and the p-type semiconductor layer 141, and thus the non-light emitting part 131 does not emit light.

The non-light emitting part 131 and the light-emitting layer 130 are only separated by the groove U1. The deposition structure of the non-light emitting part 131 is the same as that of the light-emitting layer 130 of the light-emitting part R1.

The p-electrode P1 is formed on the transparent electrode 150 above the p-type semiconductor layer 140 of the central part CNT1. The n-electrode N1 is formed on the transparent electrode 151 above the p-type semiconductor layer 141 of the outer peripheral part PRM1 (upward in the direction of arrow A). Both the p-electrode P1 and the n-electrode N1 stand from the transparent electrodes 150 and 151 disposed at the same level. Therefore, the height from the main surface 110a of the substrate 110 of the p-electrode P1 is almost equivalent to the height from the main surface 110a of the substrate 110 of the n-electrode N1.

### 3. Shape of Electrode

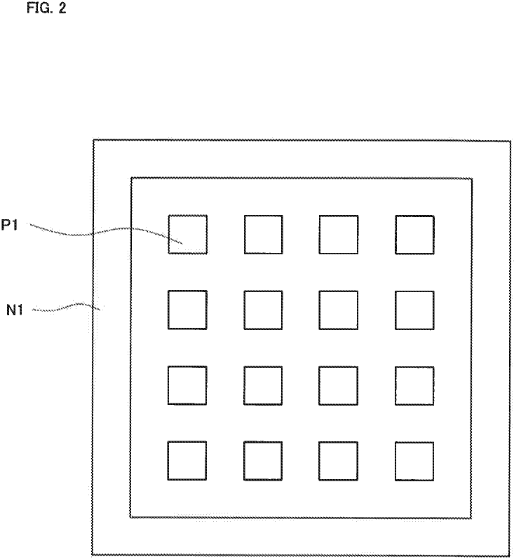

FIG. 2 shows a cross-sectional profile and arrangement of p-electrode P1 and n-electrode N1 taken along the III-III line of FIG. 1. The cross-sectional profile and the arrangement are the same as those of the p-electrode pad P2 and the n-electrode pad N2 on the driving circuit substrate 200.

The p-electrode P1 has a square planar shape. The p-electrodes P1 are arranged in a matrix, i.e., in a lattice. The p-electrodes P1 are arranged corresponding to the positions of the light-emitting parts R1 arranged in a matrix. The number of the p-electrodes P1 is equal to the number of the light-emitting parts R1.

The n-electrode N1 has a frame planar shape. The n-electrode N1 is disposed so as to surround the p-electrodes P1 arranged in a matrix. The n-electrode N1 is disposed at the outer peripheral part PRMI of the micro-LED element 100. The n-electrode N1 is common to the light-emitting parts R1 corresponding to subpixels. That is, one n-electrode N1 is formed for one micro-LED element 100.

Thus, the n-electrode N1 is disposed annularly surrounding the entire region of the light-emitting parts R1 and the p-electrodes P1, and formed on the outer peripheral part PRM1.

### 4. Outer Peripheral Part

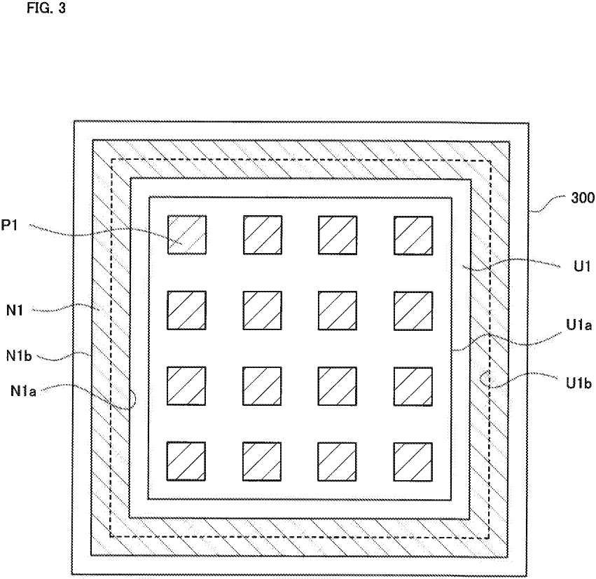

FIG. 3 is a cross-sectional view taken along the III-III line of FIG. 1. It shows the positional relationship among the p-electrode P1, the n-electrode N1, and the groove U1. The n-electrode N1 has an inside surface N1a and an outside surface N1b. The inside surface N1a is closer to the center of the micro-LED element 100. The outside surface N1b is disposed on the outer peripheral side of the micro-LED element 100.

The groove U1 is provided in the semiconductor layer to expose the n-type semiconductor layer 120. The groove U1 has a bottom surface U1c, an inner wall surface U1a, and an outer wall surface U1b. The inner wall surface U1a and the outer wall surface U1b are faced each other. The inside surface N1a of the n-electrode N1 is disposed between the inner wall surface U1a and the outer wall surface U1b of the groove U1. The outer wall surface U1b of the groove U1 is disposed between the inside surface N1a and the outside surface N1b of the n-electrode N1.

### 5. Comparison

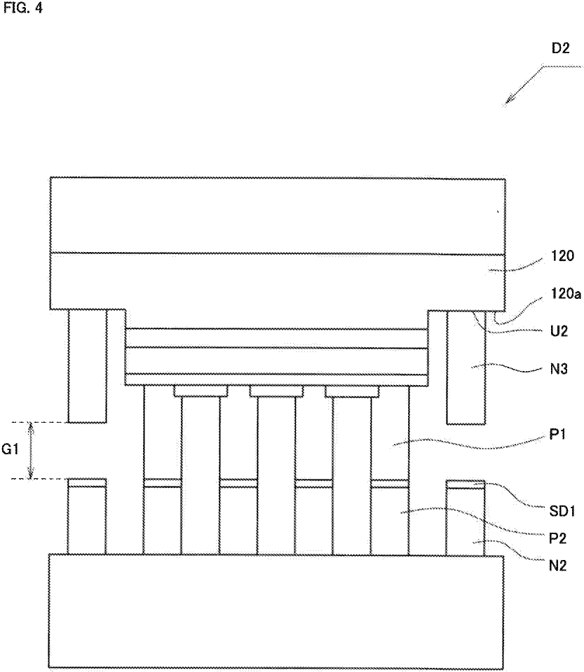

FIG. 4 shows the structure of a LED display D2 having no outer peripheral part. As shown in FIG. 4, the LED display D2 does not have an outer peripheral part. A groove U2 for forming an n-electrode N3 does not have a part corresponding to the outer wall surface. Thus, the n-electrode N3 stands from an exposed surface 120a of the n-type semiconductor layer 120,

On the other hand, a p-electrode P1 is formed on a transparent electrode above the p-type semiconductor layer. The p-electrode P1 and the n-electrode N3 are simultaneously formed in the same process. The thickness of the p-electrode P1 is almost equal to the thickness of the n-electrode N3. Therefore, a gap G1 due to a step between the n-type semiconductor layer and the transparent electrode occurs between the n-electrode N3 and the n-electrode pad N2.

Thus, a gap G1 occurs between the bonding layer SD1 on the n-electrode pad N2 and the n-electrode N3. This causes bonding failure when the micro-LED element 100 is mounted on the driving circuit substrate 200.

### 6. Effect of First Embodiment

The micro-LED element 100 of the LED display D1 according to the first embodiment includes a central part CNT1 and an outer peripheral part PRM1. The p-electrode P1 is formed on the transparent electrode 150 above the p-type semiconductor layer 140 of the central part CNT1. The n-electrode N1 is formed continuously from the bottom surface U1c of the groove U1 onto the transparent electrode 151 above the p-type semiconductor layer 141 of the outer peripheral part PRM1. Thus, a part of the n-electrode N1 is formed from an initial position at the same level as an initial position of the p-electrode P1. As a result of this, a height from the surface of the substrate 110 of the p-electrode P1 is almost same as the height from the surface of the substrate 110 of the n-electrode N1.

In this way, bonding failure can be suppressed in the n-electrode N1 disposed at the outer peripheral part PRM1 when the micro-LED element 100 is mounted on the driving circuit substrate 200. This improves the yield rate of the LED display D1.

### 7. Variations

### 7-1. Shape of N-Electrode

The n-electrode N1 is disposed so as to annularly surround the light-emitting parts R1 and the p-electrodes P1. The n-electrode N1 may have a polygonal frame shape or a curved frame shape as well as a square frame shape. That is, the n-electrode N1 may be annular.

### 7-2. Shape of P-Electrode

The p-electrode P1 of the micro-LED element 100 bonded to the p-electrode pad P2 of the driving circuit substrate 200 has a square planar shape. However, the p-electrode P1 may have a rectangular planar shape, a polygonal planar shape, and a circular planar shape.

### 7-3. Multicolor

In the first embodiment, a plurality of light-emitting parts R1 emits the same color light. However, the micro-LED element 100 may have a light-emitting part emitting three RGB color lights. In that case, the micro-LED element 100 includes a first subpixel light-emitting part, a second subpixel light-emitting part, and a third subpixel light-emitting part. The first subpixel light-emitting part has a first light-emitting layer. The second subpixel light-emitting part has a first light-emitting layer and a second light-emitting layer. The third subpixel light-emitting part has a first light-emitting layer, a second light-emitting layer, and a third light-emitting layer. The heights of the p-electrodes for subpixels are adjusted to be the same. The first light-emitting layer, the second light-emitting layer, and the third light-emitting layer have different bandgaps.

### 7-4. Others

The number of the light-emitting parts R1 is actually larger than the number of the light-emitting parts R1 shown in FIG. 2.

The transparent electrode 151 may not be formed. The region may be divided for each light-emitting part R1. In this case, the n-electrode N1 is formed on the p-type semiconductor layer 141.

The insulating layer I1 may not be formed.

The bonding layer SD1 may be SnAgCu-based solder. Moreover, other bonding method may be used, for example, vacuum deposition and ultrasonic bonding.

The aforementioned variations may be combined with one another without any restriction.

What is claimed is:

1. A LED display comprising a monolithic light-emitting element having a plurality of light-emitting parts formed on a substrate, and a driving circuit substrate having a driving circuit for supplying a current to the light-emitting element formed thereon, wherein
the light-emitting element includes the substrate, an n-type semiconductor layer, a light-emitting layer, a p-type semiconductor layer, a p-electrode, and an n-electrode,
the light-emitting parts are arranged in a matrix,
the p-electrodes are arranged in a matrix corresponding to the positions of the light-emitting parts,
the light-emitting element has a groove surrounding a central part having the light-emitting parts formed therein, and dividing a part outside the central part as an outer peripheral part, and
the n-electrode is formed annularly along the groove, being in contact with the n-type semiconductor layer exposed on a bottom surface of the groove and surrounding the central part from a top surface of the outer peripheral part, the n-electrode being not contact with an inner wall surface on the central part side of the groove.

2. The LED display according to claim 1, wherein an electrode pad for bonding the p-electrode and the n-electrode is formed on a top surface of the driving circuit substrate, and the surfaces facing the electrode pads of the n-electrode and the p-electrode are positioned on a level surface.

3. The LED display according to claim 1, wherein the n-electrode is in contact with an outer wall surface facing the inner wall surface of the groove.

4. The LED display according to claim 1, wherein the n-electrode is formed on the p-type semiconductor layer as the top layer of the outer peripheral part.

5. The LED display according to claim 1, wherein a transparent electrode is formed on the p-type semiconductor layer of the outer peripheral part, and the n-electrode is formed on the transparent electrode of the outer peripheral part.

6. The LED display according to claim 2, wherein a transparent electrode is formed on the p-type semiconductor layer of the outer peripheral part, and the n-electrode is formed on the transparent electrode of the outer peripheral part.

7. The LED display according to claim 3, wherein a transparent electrode is formed on the p-type semiconductor layer of the outer peripheral part, and the n-electrode is formed on the transparent electrode of the outer peripheral part.

8. The LED display according to claim 1, wherein the n-electrode has an outside surface facing the outside of the light-emitting element and an inside surface facing the inside of the light-emitting element, the inside surface of the n-electrode being disposed between the inner wall surface and the outer wall surface of the groove.

9. The LED display according to claim 3, wherein the n-electrode has an outside surface facing the outside of the light-emitting element and an inside surface facing the inside of the light-emitting element, the inside surface of the n-electrode being disposed between the inner wall surface and the outer wall surface of the groove.

10. The LED display according to claim 1, wherein the n-electrode is commonly formed for a plurality of the light-emitting parts.
